(19) United States
(12) Patent Application Publication
(10) Pub. No.: US 2016/0074968 A1
(43) Pub. Date: Mar. 17, 2016

(54) LASER ETCHING SYSTEM INCLUDING MASK RETICLE FOR MULTI-DEPTH ETCHING

(71) Applicants: SUSS MicroTec Photonic Systems Inc., Corona, CA (US); International Business Machines Corporation, Armonk, NY (US)

(72) Inventors: Matthew E. Souter, Tustin, CA (US); Brian M. Erwin, Lagrangeville, NY (US); Nicholas A. Polomoff, White Plains, NY (US); Christopher L. Tessler, Poughquag, NY (US)

(21) Appl. No.: 14/483,321

(22) Filed: Sep. 11, 2014

(51) Int. Cl. B23K 26/36; B23K 26/06; G03F 1/48; B23K 26/00

(52) U.S. Cl. CPC B23K 26/367; B23K 26/0042; B23K 26/009; B23K 26/0661; G03F 1/48

(57) ABSTRACT

A laser etching system includes a laser source configured to generate a plurality of laser pulses during an etching pass. A workpiece is aligned with respect to the laser source. The workpiece includes an etching material that is etched in response to receiving the plurality of laser pulses. A mask reticle is interposed between the laser source and the workpiece. The mask reticle includes at least one mask pattern configured to regulate the fluence or a number of laser pulses realized by the workpiece such that a plurality of features having different depths with respect to one another are etched in the etching material.

The present disclosure relates to laser-based etching techniques, and more specifically, to a mask reticle configured to control etching depths during laser-based etching processes.

### BACKGROUND

Various materials such as, for example, semiconductor and/or etching materials, can be etched using laser etching tools configured to generate high-energy laser pulses that pattern the workpiece. Conventional laser-based etching processes achieve a desired pattern depth by controlling the fluence of the laser pulses, the amount of time a patterned area of the workpiece is exposed to the laser pulses, and/or the amount of pulses delivered to the patterned area. In order to etch patterns having varied depths, conventional laser-based etching processes require multiple etching passes combined with multiple mask reticles to achieve a respective depth. Consequently, the laser etching tool must perform multiple passes corresponding to each mask.

### SUMMARY

According to at least one embodiment a laser etching system includes a laser source configured to generate a plurality of laser pulses during an etching pass. A workpiece is aligned with respect to the laser source. The workpiece includes an etching material that is etched in response to receiving the plurality of laser pulses. A mask reticle is interposed between the laser source and the workpiece. The mask reticle includes at least one mask pattern configured to regulate the fluence or a number of laser pulses realized by the workpiece such that a plurality of features having different depths with respect to one another are etched in the etching material following a single etching pass.

According to another embodiment, a method of etching a workpiece comprises generating a plurality of laser pulses having a fluence during an etching pass. The method further includes aligning a workpiece with respect to the plurality of laser pulses, the workpiece including an etching material that is etched in response to receiving the plurality of laser pulses. The method further includes regulating at least one of the fluence and a number of laser pulses realized by the workpiece using at least one mask pattern such that a plurality of features having different depths with respect to one another are etched in the etching material.

Additional features are realized through the techniques of the present invention. Other embodiments are described in detail herein and are considered a part of the claimed invention. For a better understanding of the invention with the features, refer to the description and to the drawings.

### BRIEF DESCRIPTION OF THE SEVERAL VIEWS OF THE DRAWINGS

The subject matter which is regarded as the invention is particularly pointed out and distinctly claimed in the claims at the conclusion of the specification. The forgoing features are apparent from the following detailed description taken in conjunction with the accompanying drawings in which:

FIG. 1 illustrates a cross-sectional view of a mask reticle interposed between a laser source and a workpiece according to an exemplary embodiment;

FIG. 2 is a close-up view illustrating the dimensions of mask reticle and corresponding feature according to an exemplary embodiment;

FIGS. 3A-3C illustrate various examples of etched features based on the dimensions of the mask reticle and the depth of the workpiece;

FIG. 4 illustrates a cross-sectional view of a mask reticle interposed between a laser source and a workpiece according to another exemplary embodiment;

FIG. 5 illustrates a cross-sectional view of a mask reticle interposed between a laser source and a workpiece according to still another exemplary embodiment;

FIG. 6 illustrates a cross-sectional view of a mask reticle interposed between a laser source and a workpiece according to yet another exemplary embodiment;

FIG. 7 illustrates a perspective view of a mask reticle having three different mask patterns configured to etch a pattern having multiple different depths in a workpiece according to an exemplary embodiment;

FIG. 8A illustrates a laser source delivering laser fluences to an etching material of a workpiece using a first pattern of the mask reticle shown in FIG. 7 during a first delivery pass according to an exemplary embodiment;

FIG. 8B illustrates the etching material of the workpiece shown in FIG. 8A including a plurality of etched features having a first depth according to the first pattern;

FIG. 9A illustrates the laser source delivering laser fluences to the etching material of a workpiece shown in FIGS. 8A-8B using the second pattern of the mask reticle shown in FIG. 6 during the first delivery pass;

FIG. 9B illustrates the etching material of the workpiece shown in FIG. 9A including a first plurality of etched features having the first depth according to the first pattern and a second plurality of etched features having a second depth according to the second pattern;

FIG. 10A illustrates the laser source delivering laser fluences to the etching material of a workpiece shown in FIGS. 9A-9B using the third pattern of the mask reticle shown in FIG. 6 during the first delivery pass; and

FIG. 10B illustrates the etching material of the workpiece shown in FIG. 10A including a first plurality of etched features having the first depth according to the first pattern, a second etched features having the second depth according to the second pattern, and a third plurality of etched features having a third depth according to the third pattern.

### DETAILED DESCRIPTION

Various embodiments of the present disclosure provide a mask reticle configured to pass laser fluences therethrough and toward a workpiece to etch a pattern having multiple different depths. In this manner, the mask reticle provided by at least one embodiment provides greater cost savings, while also decrease processing time, wear on the tool, and the use of consumables required to operate the laser.

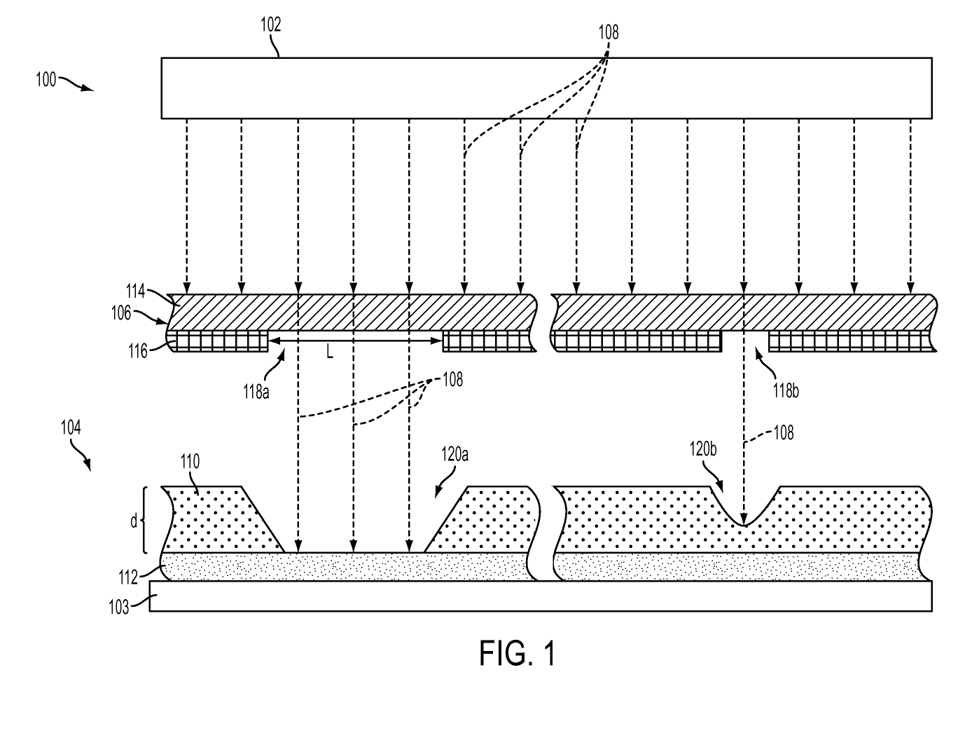

With reference now to FIG. 1, a laser etching system 100 is illustrated according to an exemplary embodiment. The laser etching system 100 includes a laser source 102 including a stage 103 to support a workpiece 104, and a mask reticle 106 interposed between the laser source 102 and the stage 103.

The laser source 102 may include any commercially available laser source such as one capable of generating one or more ultra violet (UV) laser pulses 108 having a wavelength of, for example, approximately 308 nanometers (nm). A representative high energy UV pulse 108 may include fluences ranging, for example, from approximately 0.05 joules (J) to approximately 1.0 J per square centimeter (cm), and a pulse duration of approximately 1 nanosecond(ns) to approximately 100 ns, for example. The wavelength of the UV pulse 108 may include all wavelengths produced by an excimer laser such as, for example, approximately 126 nm to approximately 351 nm, and/or other wavelengths, without limitation.

The workpiece 104 includes an etching material 110 formed on an etch-resistant base 112. The etching material may be formed from, for example, a dielectric material. The dielectric material includes, but is not limited to, photodefinable polymers, polyimides (PI), polybenzobisoxazole (PBO), epoxies, and bisbenzocyclobutene (BCB).

The mask reticle 106 includes a transparent layer 114 having a reflective layer 116 formed on an upper surface thereof. The transparent layer 114 is formed from various laser transparent materials including, but not limited to, quartz. The reflective layer 116 is formed from various reflective materials including, but not limited to, aluminum. According to an embodiment, a first opening 118a has a first critical dimension and a second opening 118b has a second critical dimension that is less than the first critical dimension. The mask reticle 106 can be interposed between the laser source 102 and the workpiece 104. Although the masking reticle 106 is illustrated with the openings 118a, 118b, etc., disposed below the transparent layer 114, it is appreciated that the masking reticle 106 can be formed such that the openings 118a, 118b, etc., are disposed above the transparent layer 114.

According to an embodiment, laser pulses 108 generated by the laser source 102 are directed toward the mask reticle 106 during a single etching pass. The reflective layer 116 prevents the laser pulses 108 from penetrating therethrough and reaching the workpiece 104. The openings 118a/118b, however, allow portions of the pulses 108 to pass through the transparent layer 114 and reach the workpiece 104 disposed beneath the mask reticle 106 to form corresponding openings 120a/120b. The size of the openings 118a/118b limits the area where energy is applied to the workpiece 104. If the applied area is sufficiently small, the sloping of sidewall features will intercept one another and self-limit the ablation process. For example, the applied area can have a dimension that is, for example, less than the thickness of the layer being etched.

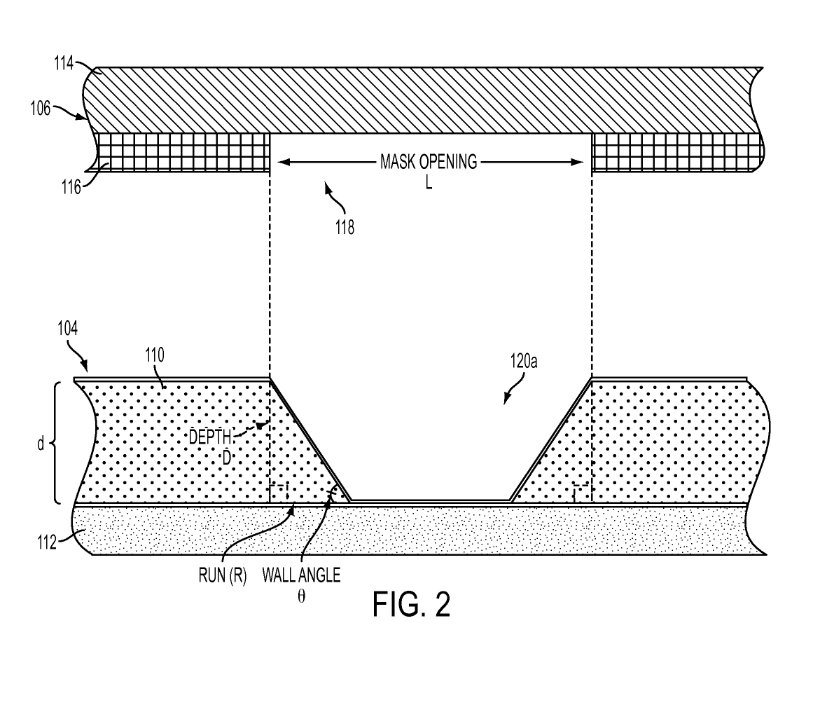

Turning to FIG. 2, a close-up view of the mask reticle 106 illustrating the dimensions of the first opening 118a and corresponding feature 120a, for example, are shown. The size (l) of the opening 118a in the mask reticle 106 determines the largest size of the etched feature 120a. It is appreciated that the size of the etched feature 120a can vary from the size of the mask reticle 106 if the optics alter the magnification (not shown). The wall angle/slope (θ) is dependent on the material 110, laser fluence, and laser wavelength. The etched depth (d) is dependent on the material 110, laser fluence, laser wavelength, and the number of laser pulses. The etch depth (d) and the wall angle/slope define the run (r), i.e., the length of material under the sloped side wall, where r=tan(θ)/d. If the etched opening, l<2*tan(θ)/d, then the etched opening of the feature 120a will self-limit.

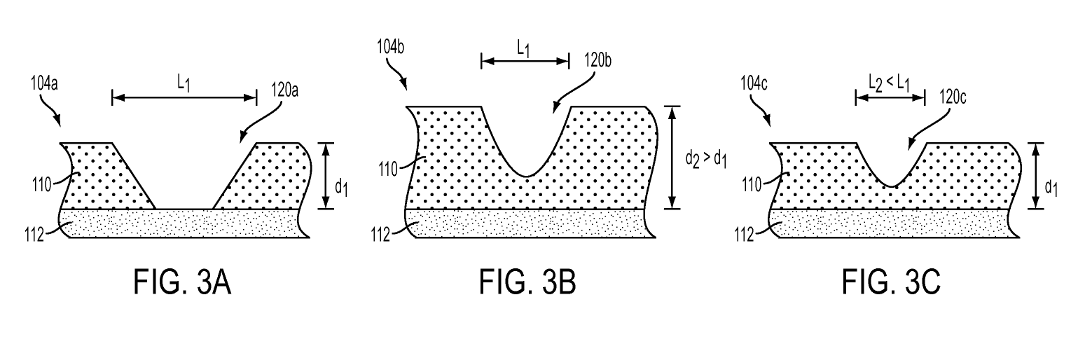

Various examples of a feature 120 etched in a workpiece 104 are illustrated in FIGS. 3A-3C. In FIG. 3A, a workpiece 104a is illustrated including a feature 120a is etched into an etching material 110a having a first depth (d₁). The feature 120a is formed using a masking opening (not shown) having a size of (l₁). The feature 120a extends completely through the material 110a and stops on an underlying etch-resistant base 112a. The feature 120a has an upper opening 121a with a size (l₁) that is approximately equal to the size (l₁) of the mask opening.

In FIG. 3B, a workpiece 104b is illustrated including an etching material 110b having a second depth (d₂) being greater than the depth (d₁) of the etching material 110a illustrated in FIG. 3A. The feature 120b is etched using a mask opening having a size (l₁) similar to that of the mask opening used to form the feature 120a in FIG. 3A. Accordingly, the feature 120b has an upper opening 121b with a size (l₁) that is approximately equal to the size (l₁) of the mask opening. Due to the increase in the depth (d₂), however, the feature 120b partially extends through the etching material 110b and self-limits instead of etching completely through the etching material 110b and stopping on the underlying etch-resistant base 112b.

Turning to FIG. 3C, a workpiece 104c is illustrated including a feature 120c etched into an etching material 110c. The etching material 110c has a depth (d₁) similar to the depth (d₁) of the etching material 110a described in FIG. 3A. In this case, however, the size (l₂) of the opening used to form the feature 120c is smaller than the size (l₁) of the opening used to form the feature 120a in FIG. 3A. In this manner, the feature 120c partially extends through the material 110c and self-limits instead of etching completely through the etching material 110c and stopping on the underlying etch-resistant base 112c.

Referring again to FIG. 1, the depth of a second feature 120b etched in the etching material 110 using the second opening 118b (e.g., smaller opening) is controlled by the laser fluence, but not the number of pulses applied. The material and the wavelength of the laser also can control the depth of second feature 120b. For instance, the depth of the second feature 120b is determined by the width of the etched l and the wall angle/slope θ. The etched material, laser fluence, and laser wavelength can also affect the depth of the second feature 120b. For example, when the material and the wavelength are fixed, the via sidewall angle is fixed and the number of pulses become insignificant at moderate fluences ranging, for example, from approximately 100 millijoules per square centimeter (mJ/sq cm) to approximately 400 mJ/sq cm.

In response to increasing the fluence, the additional energy introduced to the etching material 110 improves the ability to overcome the etching threshold (i.e., the threshold at which the etching material begins to breakdown due to exposure from the pulses 108) such that one or more second features 120b are formed as self-limiting features 120b. In cases where the fluence is remains constant, the self-limiting features 120b are formed having approximately identical sidewalls, while lower fluences will produce a termination depth that is shallower. Additional pulses 108 at a low fluence will not help overcome the etching threshold of the side walls.

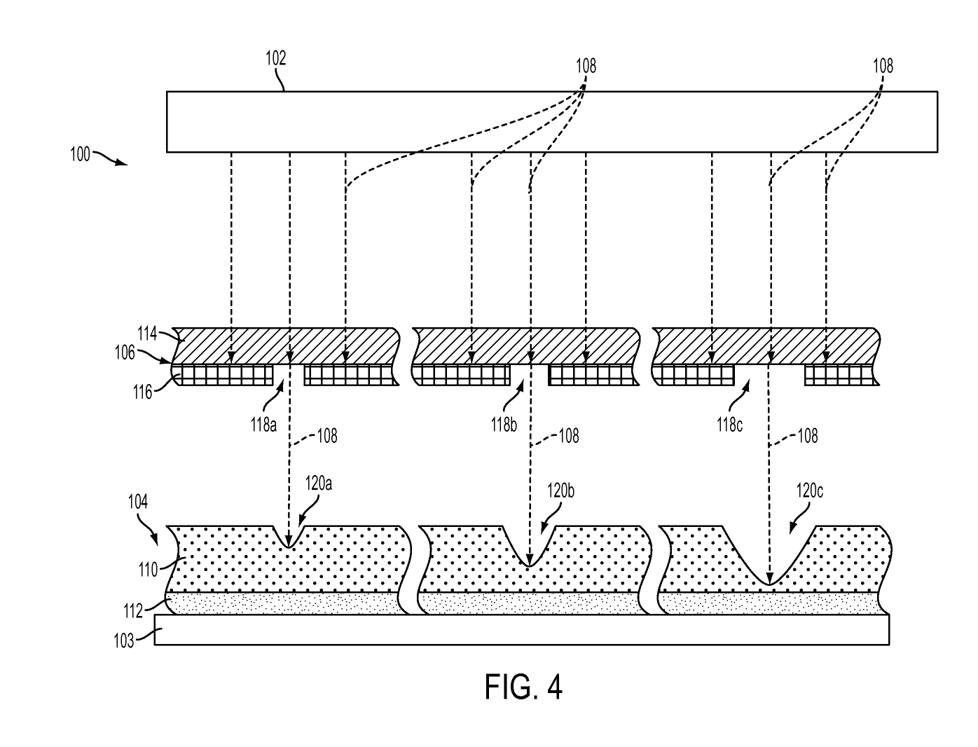

Turning now to FIG. 4, a laser etching system 100 is illustrated according to another exemplary embodiment. The laser etching system 100 includes a mask reticle 106 interposed between a laser source 102 and a workpiece 104. The workpiece 104 and the mask reticle 106 are formed from similar materials as described in detail above. The mask reticle 106 is formed with a plurality of openings 118a-118c having different sizes with respect to one another. Laser pulses 108 are allowed to pass through the openings 118a-118c to etch respective features 120a-120c into the etching material 110.

The etched features 120a-120c are formed with a depth and size that are proportional to the size of the openings 118a-118c. For example, a first opening 118a having the smallest size among the openings 118a-118c facilitates the formation of a first feature 120a having the shallowest depth among the etched features 120a-120c, while a third opening 118c having the largest size among the openings 118a-118c facilitates the formation of a third feature 120c having the deepest depth. Accordingly, the variation in sizes of the openings 118a-118c facilitates the formation of respective self-limited features 120a-120c having different depths with respect to one another.

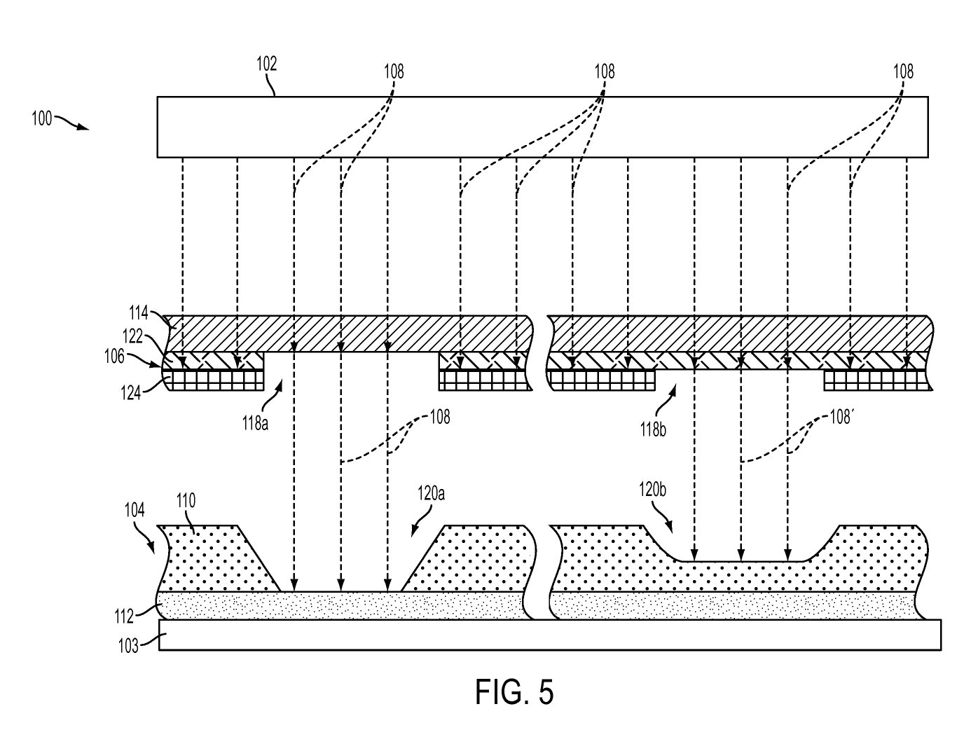

With respect to FIG. 5, a laser etching system 100 is illustrated according to another exemplary embodiment. The laser etching system 100 includes a mask reticle 106 interposed between a laser source 102 and a workpiece 104. The workpiece 104 and the mask reticle 106 are formed from similar materials as described in detail above. The mask reticle 106, however, includes a stacked reflection layer having multiple sub-layers configured to etch the workpiece 104 at multiple etch rates. More specifically, the mask reticle 106 includes a partially-reflective sub-layer 122 and a fully-reflective sub-layer 124. The partially-reflective sub-layer 122 includes a tinted film that reflects, for example, approximately 20% to approximately 80% of the incident energy of the laser pulses 108 and is formed on an upper surface of the transparent layer 114. The fully-reflective sub-layer 124 reflects, for example, approximately 99%-100% of the incident energy of the laser pulses 108 and is stacked directly on the partially-reflective sub-layer 122.

A first portion of mask reticle 106 is patterned to form a first opening 118a that extends through both the partially-reflective sub-layer 122 and the fully-reflective sub-layer 124. A second portion of the mask reticle 106 is patterned to form a second opening 118b that extends through only the fully-reflective sub-layer 124 to expose an underlying portion of the partially-reflective sub-layer 122. The first opening 118a allows the full fluence of the laser pulses 108 to pass through the transparent layer 114 while the second opening 118b allows only a partial fluence of the laser pulses 108′ to pass through the transparent layer 114. Accordingly, the full-fluence laser pulses 108 form a fully-etched feature 120a into the etching material 110 while the partial-fluence laser pulses 108′ form a partially-etched feature 120b into the etching material 110. In addition, the fluence of the laser pulses 108 and the number of laser pulses 108 can be adjusted to control the dimensions of the etched features 120a/120b. For example, increasing the fluence of the laser pulses 108 and the number of laser pulses 108 directed toward the mask reticle 106 increases the depth of the etched features 120a/120b. It is appreciated that a change to the fluence that etches 120a, however, may have no impact in the etch depth. Increasing or decreasing the fluence of the laser pulses 108 also increases or decreases, respectively, the angle of the sidewalls defined by each feature 120a/120b. To this end, by decreasing the laser fluence, the etched feature 120a may only extend partially through the etching material 110 (similar to feature 120b), or the partially etched via 102b (and possibly the fully etched via 102a) and may become self-limiting as the wall angle/slope decreases due to the fluence reduction.

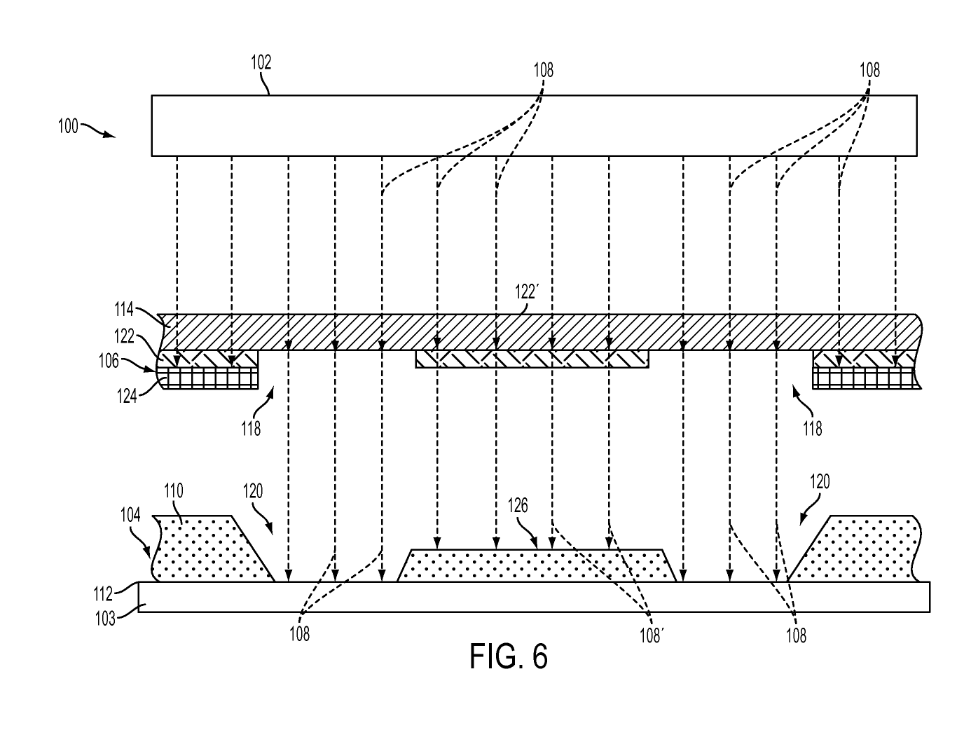

Referring now to FIG. 6, a laser etching system 100 is illustrated according to another exemplary embodiment. The laser etching system 100 includes a mask reticle 106 interposed between a laser source 102 and a workpiece 104. The workpiece 104 and the mask reticle 106 are formed from similar materials as described in detail above. The mask reticle 106 also includes a stacked reflection layer having multiple sub-layers configured to etch the workpiece 104 at multiple etch rates. The mask reticle 106 includes a partially-reflective sub-layer 122 and a fully-reflective sub-layer 124 as described in detail above.

According to at least one embodiment, the stacked reflection layer is patterned such that a single isolated partially-reflective sub-layer 122′ is interposed between the first and second openings 118. Stacked reflection layers are formed on the transparent layer 114. The stacked reflection layers include a fully-reflective sub-layer 124 stacked directly on a partially-reflective sub-layer 122 as described above. Each opening 118 separates a respective stacked reflection layer from the isolated partially-reflective sub-layer 122′. The openings 118 extend through the partially-reflective sub-layer 122 and the fully-reflective sub-layer 124 and expose the transparent layer 114. Accordingly, full-fluence laser pulses 108 pass through the openings 118 to reach the etching material 110 and etch a first feature 120 therein.

The first feature 120 is, for example, a fully-etched feature 120 that exposes a portion of the underlying base 112. The isolated partially-reflective sub-layer 122′, however, reduces the fluence of the laser pulses 108 without completely blocking the laser pulses 108 from passing through the transparent layer 114. Accordingly, partial-fluence laser pulses 108′ impinge on the etching material 110 and form a partially-etched isolated feature 126 that is interposed between the fully-etched features 120. In this manner, the fully-etched features 120 and the partially-etched isolated feature 126 can enable the formation of electrically conductive interconnects, for example, which connect one or more vias using various plate up and dual-damascene fabrication processes as understood by those having ordinary skill in the art. It is appreciated that similar sets of features can be formed in a single pass utilizing varied etch feature openings and the techniques described above with respect to FIGS. 1-5.

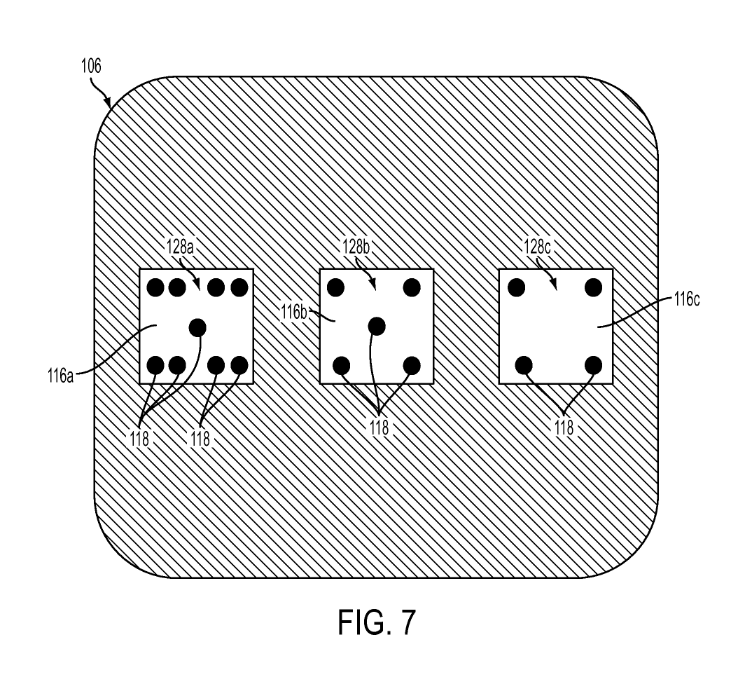

Turning to FIG. 7, a perspective view of a mask reticle 106 is illustrated according to an exemplary embodiment. The mask reticle 106 includes a plurality of individual reflective layers 116a-116c formed thereon. Each reflective layer 116a-116c includes a different arrangement of openings that defines a respective mask pattern. For example, a first reflective layer 116a includes a plurality of openings 118 that defines a first mask pattern 128a, a second reflective layer 116b includes a plurality of openings 118 that defines a second mask pattern 128b, and a third reflective layer 116c includes a plurality of openings 118 that defines a third mask pattern 128c.

The position of the mask reticle 106 is adjustable with respect to one or more laser pulses 108. According to an embodiment, the mask reticle 106 may be supported by a moveable mask stage (not shown in FIG. 7). The mask stage can position the mask reticle 106 between a laser source 102 and a stage 103 that supports a workpiece 110. According to another embodiment, the stage 103 is configured to move and can align the workpiece 104 with respect to one or more of the mask patterns 128a-128c. In this manner, a specific pattern of features having varying depths can be etched into a workpiece by aligning the mask patterns 128a-128c with the laser pulses 108 and the workpiece 104 according to one or more sequences as discussed in greater detail below.

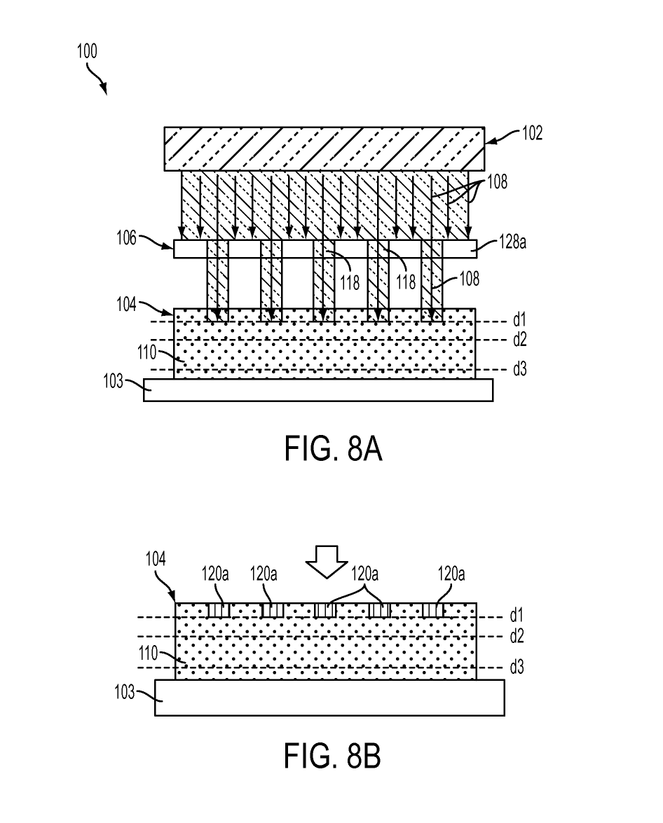

A sequence of alignment operations that align the masking patterns 128a-128c with respect to a plurality of laser pulses 108 and a workpiece 104 is illustrated with reference to FIGS. 8A-10B according to an exemplary embodiment. In FIG. 8A, the first masking pattern 128a is interposed between a plurality of laser pulses 108 and the workpiece 104. A first portion of laser pulses 108 are conveyed through openings 118 that define the first masking pattern 128a. The laser pulses 108 impinge an upper surface of an etching material 110 formed on the workpiece 104 and etch a first plurality of features 120a. The first plurality of features 120a extend into the etching material 110 at a first depth (d1) as illustrated in FIG. 8B.

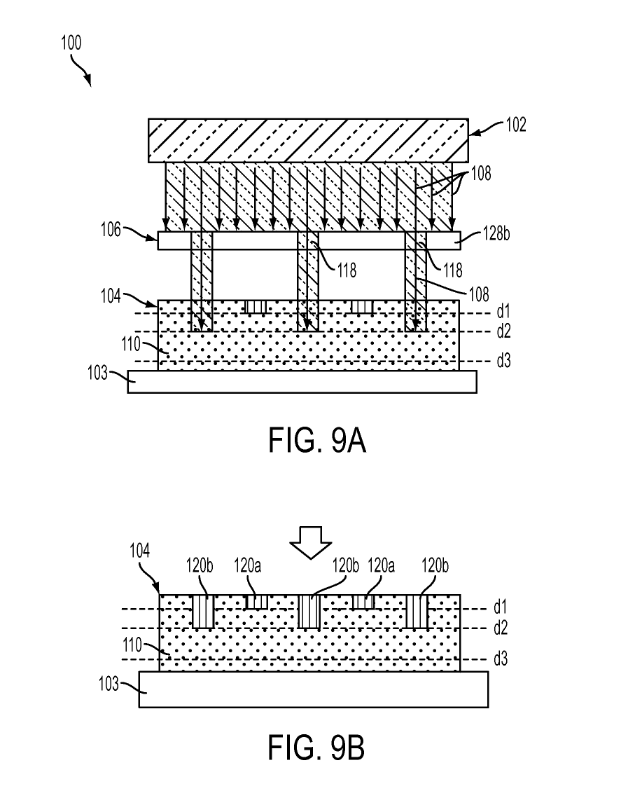

In FIG. 9A, the second masking pattern 128b is interposed between the laser pulses 108 and the workpiece 104. A second portion of laser pulses 108 are conveyed through openings 118 that define the second masking pattern 128b. The laser pulses 108 increase the depth of the one or more first features 120a. In this manner, one or more second features 120b are formed which extend into the etching material 110 at a second depth (d2) that is greater than d1. Accordingly, the etching material 110 is formed with a plurality of first features 120a extending into the etching material 110 at a first depth d1, and a plurality of second features 120b extending into the etching material 110 at a second depth d2 as illustrated in FIG. 9B.

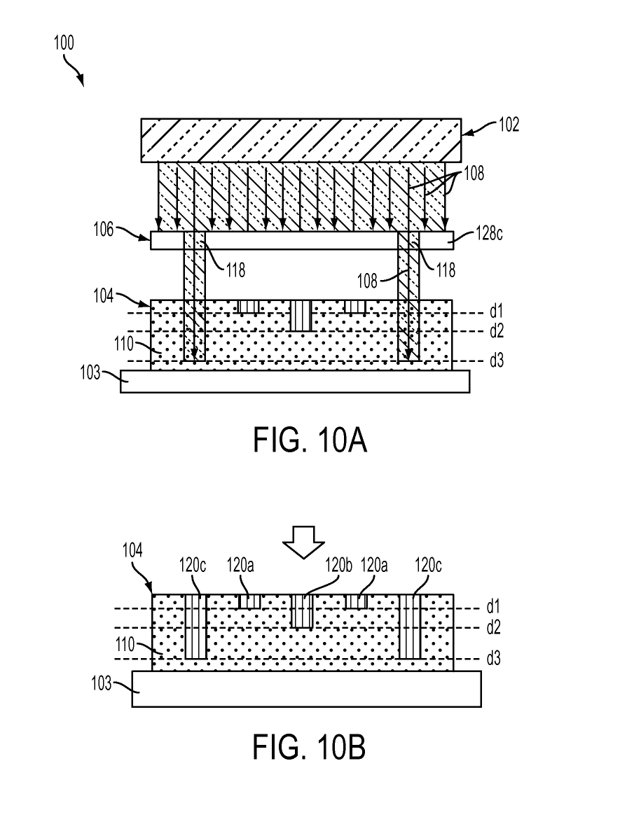

In FIG. 10A, the third masking pattern 128c is interposed between the laser pulses 108 and the workpiece 104. A third portion of laser pulses 108 are conveyed through openings 118 that define the third masking pattern 128c. The laser pulses 108 increase the depth of one or more second features 120b. In this manner, one or more third features 120c are formed which extend into the etching material 110 at a third depth (d3) that is greater than d1 and d2. Accordingly, the etching material 110 is formed with at least one first feature 120a extending into the etching material 110 at a first depth d1, at least one second features 120b extending into the etching material 110 at a second depth d2, and at least one third features 120c extending into the etching material 110 at a third depth d3 as illustrated in FIG. 10B.

With reference still to FIGS. 8A-10B, the depth of the first features 120a formed using the first mask pattern 128a is predicated on the fluence level and the number of pulses 108 delivered to the etching material 110. By controlling the number of pulses 108 delivered for any given pattern, the depth of the first pattern can be selected to be any desired depth. Following positioning of the second mask pattern 128b, one or more selected first features 120a can continue to be laser etched to achieve a desired depth or stop layer. It is appreciated that the positioning of the mask patterns 128a-128c does not require any particular sequence of alignment operations in order or overlap one another to continue etching further into the etching material 110 and achieve summed etch depths.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the inventive teachings and the practical application, and to enable others of ordinary skill in the art to understand the invention for various embodiments with various modifications as are suited to the particular use contemplated

The flow diagrams depicted herein are just one example. There may be many variations to this diagram or the operations described therein without departing from the spirit of the invention. For instance, the operations may be performed in a differing order or operations may be added, deleted or modified. All of these variations are considered a part of the claimed invention.

While various embodiments have been described, it will be understood that those skilled in the art, both now and in the future, may make various modifications which fall within the scope of the claims which follow. These claims should be construed to maintain the proper protection for the invention first described.

What is claimed is:

1. A method of etching a workpiece, the method comprising:
generating a plurality of laser pulses having a fluence during an etching pass;
aligning a workpiece with respect to the plurality of laser pulses, the workpiece including an etching material that is etched in response to receiving the plurality of laser pulses; and
regulating at least one of the fluence and a number of laser pulses among the plurality of laser pulses received at the workpiece using at least one mask pattern formed on a mask reticle such that a plurality of features having different depths with respect to one another are etched in the etching material.

2. The method of claim 1, conveying a first set of laser pulses among the plurality of laser pulses through at least one first opening of the at least one mask pattern and toward the workpiece during a first etching pass to etch a first feature among the plurality of features into the etching material, and conveying a second set of laser pulses among the plurality of laser pulses through at least one second opening of the at least one mask pattern and toward the workpiece during the first etching pass to etch a second feature among the plurality of features into the etching material.

3. The method of claim 2, further comprising passing a first number of laser pulses among the first set of laser pulses through the at least one first opening having a first size and passing a second number of laser pulses among the second set of laser pulses through the at least one second opening having a second size different from the first size, the second number of laser pulses being different from the first number of laser pulses.

4. The method of claim 3, wherein a depth of the first and second features etched in the etching material is proportional to a size of a respective opening.

5. The method of claim 4, wherein the mask reticle comprises:
a fully-reflective layer formed on an upper surface of a transparent layer, the at least one first and second openings being formed in the fully-reflective layer such that a portion of the transparent layer is exposed,
wherein the fully-reflective layer is configured to reflect the plurality of laser pulses incident there upon, and the transparent layer is configured to pass the plurality of laser pulses to the workpiece.

6. The method of claim 2, further comprising passing the first set of laser pulses through the at least one first opening to generate a first fluence and passing the second set of laser pulses through the at least one second opening to generate a second fluence that is less than the first fluence.

7. The method of claim 6, further comprising disposing a partially reflective layer in the at least one second opening to reduce the fluence of laser pulses passing therethrough.

8. The method of claim 7, further comprising:
forming a reflective layer on an upper surface of a transparent layer;
forming a partially reflective layer directly on the transparent layer; and
forming a fully reflective layer formed directly and partially on the partially reflective layer, the transparent layer, the stacked reflective layer, the partially reflective layer, and the full reflective layer forming the mask reticle.

9. The method of claim 8, wherein the first opening extends through the partially reflective layer and the fully reflective layer to expose the transparent layer, and the second opening extending through only the fully reflective layer to expose the partially reflective layer.

10. The method of claim 9, wherein the transparent layer exposed by the first opening is configured to pass a first set of laser pulses having a first fluence, and a combination of the partially reflective layer and the transparent layer is configured to pass a second set of laser pulses having a second fluence that is less than the first fluence.

11. The method of claim 2, wherein the at least one first opening defines a first mask pattern on the mask reticle and the at least one second opening defines a second mask pattern on the mask reticle different from the first mask pattern.

12. The method of claim 11, wherein the first pattern is aligned during a first pass to form a first feature having a first depth and a second feature having a second depth, and the second pattern is aligned during a second pass to extend the depth of one of the first feature or the second feature.

13. The method of claim 2, wherein the plurality of features having different depths with respect to one another are etched in the etching material during a single etching pass.

14. A mask reticle included in a laser etching system, the mask reticle comprising:
a transparent layer configured to pass full fluence of a laser pulse therethrough;
a reflective layer stacked on the transparent layer, the reflective layer configured to block a laser pulse from passing therethrough; and
at least one mask pattern formed in a portion of the reflective layer to convey a plurality of laser pulses passing by the reflective layer, the at least one mask pattern configured to regulate at least one of fluence and a number of laser pulses passing therethrough to control a depth of at least one etching feature.

15. The mask reticle of claim 14, wherein the at least one mask pattern includes at least one first opening and at least one second opening, the at least one first opening configured to convey a first set of laser pulses among the plurality of laser pulses to the workpiece during a first etching pass and the at least one second opening configured to convey a second set of laser pulses among the plurality of laser pulses to the workpiece during the first etching pass.

16. The mask reticle of claim 15, wherein the at least one first opening has a first size configured to pass a first number of laser pulses among the first set of laser pulses therethrough and the at least one second opening has a second size different from the first size to pass a second number of laser pulses among the second set of laser pulses therethrough, the second number of laser pulses being different from the first number of laser pulses.

17. The mask reticle of claim 16, wherein the first opening and the second opening are configured to form a depth in the etching material that is proportional to the size and the second size, respectively.

18. The mask reticle of claim 17, wherein the mask reticle comprises:
a fully-reflective layer formed on an upper surface of a transparent layer, the first and second openings formed in the fully-reflective layer such that a portion of the transparent layer is exposed,
wherein the fully-reflective layer is configured to reflect the plurality of laser pulses and the transparent layer is configured to pass the plurality of laser pulses to the workpiece.

19. The mask reticle of claim 15, wherein the first opening is configured to convey the first set of laser pulses having a first fluence and the second set of laser pulses is configured to convey the second set of laser pulses having a second fluence that is less than the first fluence.

20. The mask reticle of claim 19, wherein a partially reflective layer is disposed in the second opening, the partially reflective layer configured to reduce the fluence of laser pulses passing therethrough.

21. The mask reticle of claim 20, wherein the mask reticle comprises:
a stacked reflective layer formed on an upper surface of a transparent layer, the stacked reflective layer comprising:
a partially reflective layer formed directly on the transparent layer; and
a fully reflective layer stacked directly on the partially reflective layer.

22. The mask reticle of claim 21, wherein the first opening extends through the partially reflective layer and the fully reflective layer to expose the transparent layer, and the second opening extending through only the fully reflective layer to expose the partially reflective layer.

23. The mask reticle of claim 22, wherein the transparent layer exposed by the first opening is configured to pass a first set of laser pulses having a first fluence, and a combination of the partially reflective layer and the transparent layer is configured to pass a second set of laser pulses having a second fluence that is less than the first fluence.

24. The mask reticle of claim 15, wherein the at least one first opening defines a first mask pattern on the mask reticle and the at least one second opening defines a second mask pattern on the mask reticle different from the first mask pattern.

25. The mask reticle of claim 24, wherein the first pattern is configured to form a first feature having a first depth in response to conveying laser pulses generated during the first etching pass and wherein the second pattern is configured to extend the first depth in response to conveying laser pulses generated during the first etching pass.

26. A laser etching system, comprising:
a laser source configured to generate a plurality of laser pulses having a fluence during an etching pass;
a stage configured to align a workpiece with respect to the laser source, the workpiece including an etching material that is etched in response to receiving the plurality of laser pulses; and
a mask reticle interposed between the laser source and the workpiece, the mask reticle including at least one mask pattern configured to regulate at least one of the fluence and a number of laser pulses realized by the workpiece such that a plurality of features having different depths with respect to one another are etched in the etching material.

27. The laser etching system of claim 26, wherein the at least one mask pattern includes at least one first opening and at least one second opening, the at least one first opening configured to convey a first set of laser pulses to the workpiece during a first etching pass performed by the laser source and the at least one second opening configured to convey a second set of laser pulses to the workpiece during the first etching pass.

28. The laser etching system of claim 27, wherein the at least one first opening has a first size configured to pass a first number of laser pulses therethrough and the at least one second opening has a second size different from the first size to pass a second number of laser pulses therethrough, the second number of laser pulses being different from the first number of laser pulses.

29. The laser etching system of claim 28, wherein a depth of each feature etched in the etching material is proportional to a size of a respective opening.

30. The laser etching system of claim 29, wherein the mask reticle comprises:
a fully-reflective layer formed on an upper surface of a transparent layer, the first and second openings formed in the fully-reflective layer such that a portion of the transparent layer is exposed,
wherein the fully-reflective layer is configured to reflect the plurality of laser pulses and the transparent layer is configured to pass the plurality of laser pulses to the workpiece.

31. The laser etching system of claim 27, wherein the first opening is configured to convey the first set of laser pulses having a first fluence and the second set of laser pulses is configured to convey the second set of laser pulses having a second fluence that is less than the first fluence.

32. The laser etching system of claim 31, wherein a partially reflective layer is disposed in the second opening and is aligned between the plurality of laser pulses and the workpiece, the partially reflective layer configured to reduce the fluence of laser pulses passing therethrough.

33. The laser etching system of claim 32, wherein the mask reticle comprises:
a stacked reflective layer formed on an upper surface of a transparent layer, the stacked reflective layer comprising:
a partially reflective layer formed directly on the transparent layer; and
a fully reflective layer stacked directly on the partially reflective layer.

34. The laser etching system of claim 33, wherein the first opening extends through the partially reflective layer and the fully reflective layer to expose the transparent layer, and the second opening extending through only the fully reflective layer to expose the partially reflective layer.

35. The laser etching system of claim 34, wherein the transparent layer exposed by the first opening is configured to pass a first set of laser pulses having a first fluence, and a combination of the partially reflective layer and the transparent layer is configured to pass a second set of laser pulses having a second fluence that is less than the first fluence.

36. The laser etching system of claim 27, wherein the at least one first opening defines a first mask pattern on the mask reticle and the at least one second opening defines a second mask pattern on the mask reticle different from the first mask pattern.

37. The laser etching system of claim 36, wherein the first pattern is aligned during a first pass to form a first feature having a first depth and a second feature having a second depth, and the second pattern is aligned during a second pass to extend the depth of one of the first feature or the second feature.

38. The laser etching system of claim 26, wherein the plurality of features having different depths with respect to one another are etched in the etching material during a single etching pass executed by the laser source.
